(19) United States
(12) Patent Application Publication
(10) Pub. No.: US 2004/0124505 A1
(43) Pub. Date: Jul. 1, 2004

(54) Semiconductor device package with leadframe-to-plastic lock

(76) Inventors: Richard L. Mahle, McKinney, TX (US); Don L. Simpson, Sherman, TX (US)

Correspondence Address: TEXAS INSTRUMENTS INCORPORATED, P O BOX 655474, M/S 3999, DALLAS, TX, 75265

(21) Appl. No.: 10/331,669

(22) Filed: Dec. 27, 2002

(51) Int. Cl. H01L 23/495

(52) U.S. Cl. 257/666

(57) ABSTRACT

Methods for manufacturing a semiconductor device package (10) with a leadframe (14) to plastic (12) mold lock are disclosed along with the associated package (10). A method of the invention discloses manufacturing a packaged semiconductor device (10) using steps for forming a leadframe (14) with at least one borehole (20). The borehole (20) region of the leadframe (14) is coined such that a lip (34) is formed at the junction of the borehole (20) and a leadframe (14) surface. Encapsulating the lip (34) with mold compound (12) forms a leadframe (14) to plastic (12) lock incorporated in the completed semiconductor device package (10).

### TECHNICAL FIELD

The invention relates to a semiconductor device package. More particularly, the invention relates to semiconductor device packages incorporating a mold lock into a leadframe and methods for making the same and to leadframe-to-plastic lock structures and methods for use in semiconductor device packages.

### BACKGROUND OF THE INVENTION

It is well known to encapsulate semiconductor devices in packages in order to protect the device and to provide connective leads for coupling the terminals of the device to the outside world, such as a PC board.

Problems are encountered with packaged semiconductor devices used in the arts both in the manufacturing stages and in testing and use. Among the problems, some of the most common and debilitating are the separation of layers of devices, lead fingers pulling out of the package, and open or short circuits caused by separation of materials or the ingress of moisture between separated or partially materials. Attempts to improve the bond between leadframes and package materials have been made using stamped or etched vias in the leadframes, which are then filled with encapsulant. Although somewhat resistant to sheering, these efforts have enjoyed limited success.

Improved leadframe-to-plastic semiconductor device packages would be useful and advantageous in the arts. Such packages would provide increased resistance to sheering and separating forces providing a more secure bond.

### SUMMARY OF THE INVENTION

In carrying out the principles of the present invention, in accordance with an embodiment thereof, a method of making a semiconductor device package includes steps of forming a leadframe and forming at least one borehole in the leadframe. A step of stamping which includes coining a portion of the leadframe having at least one borehole is performed such that a lip is provided at the junction of the borehole and a surface of the leadframe. A step of encapsulating the lip with mold compound is also included.

According to one aspect of the invention, a semiconductor device package is manufactured by forming a leadframe having a die pad and a plurality of lead fingers. Boreholes, either partial or through-holes, are formed in the leadframe, at least one of the boreholes being provided with a lip. A step is included for encapsulating the lip, thus forming a mold lock for the semiconductor device package.

According to another aspect of the invention, a semiconductor device package is provided. The semiconductor device package includes a leadframe. The leadframe has a borehole with a lip at the junction of the borehole and leadframe surface. Mold compound is provided in the borehole for encapsulating the lip.

Exemplary embodiments of the invention are provided wherein boreholes perforate through the leadframe and lips are formed at one or more of the junctions of the borehole and upper and/or lower leadframe surfaces. Mold compound encapsulates the lips, forming a securely locked semiconductor device package.

The invention provides technical advantages including but not limited to providing a semiconductor device package ensuring a secure mechanical bond between the leadframe and encapsulant. The invention may be used advantageously to provide improved bonds for lead fingers or die pads in DIP, QFN, SOP, or other types of semiconductor device packages. The invention may be practiced with known semiconductor device package processes. These and other features, advantages, and benefits of the present invention will become apparent to one of ordinary skill in the art upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 is a top view of a preferred embodiment of the invention with encapsulant removed showing a surface of the leadframe;

FIGS. 2A through 2E illustrate examples of steps in manufacturing a semiconductor device package according to preferred embodiments of the invention;

FIG. 2A is a sectional view of a portion of a masked leadframe prior to etching;

FIG. 2B is a sectional view of the portion of a leadframe of FIG. 2A having a borehole formed in one surface;

FIG. 2C is a sectional view of the portion of a leadframe of FIG. 2B having a coined surface;

FIG. 2D is a top view showing a portion of a leadframe as in the example of FIG. 2C;

FIG. 2E is a sectional view of the portion of a leadframe as in the example of FIGS. 2C and 2D encapsulated to form a semiconductor package according to the invention;

FIG. 3 is a sectional view of a portion of a leadframe in an example of an alternative embodiment of the invention having lips at both top and bottom surfaces of the leadframe;

FIG. 4 is a sectional view of the example of a semiconductor package of FIG. 1 taken along line 4-4; and

FIG. 5 is a process flow diagram illustrating steps according to one example of a preferred method of the invention.

References in the detailed description correspond to like references in the figures unless otherwise noted. Like numerals refer to like parts throughout the various figures. Descriptive and directional terms used in the written description such as upper, lower, left, right, etc., refer to the drawings themselves as laid out on the paper and not to physical limitations of the invention unless specifically noted. The drawings are not to scale, and some features of embodiments shown and discussed are simplified or exaggerated for illustrating the principles, features, and advantages of the invention.

### DETAILED DESCRIPTION OF PREFERRED EMBODIMENTS

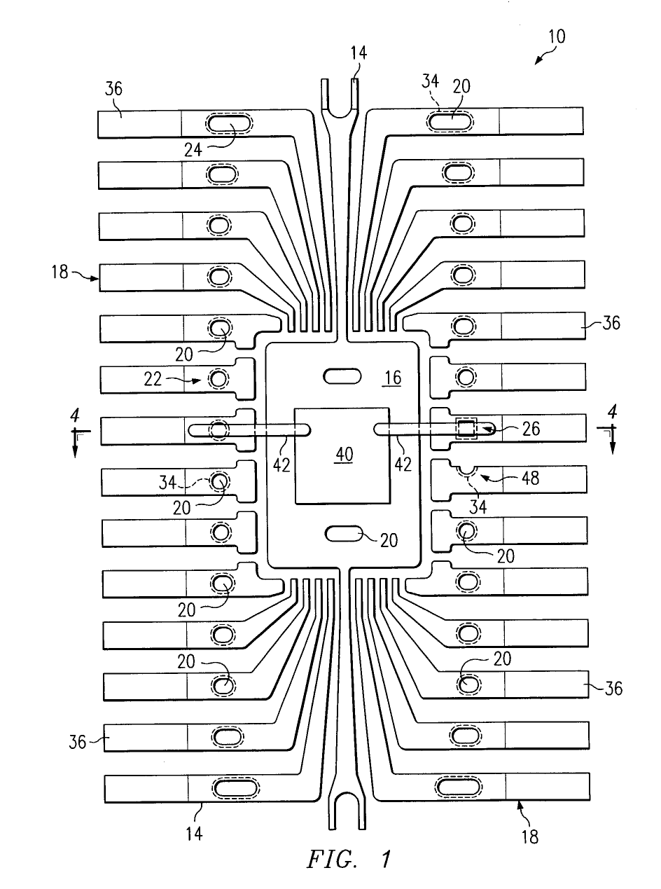

In general, the invention provides a semiconductor device package with a leadframe mold lock and methods for making the same. Referring now primarily to FIG. 1, a top view of an example of a semiconductor device package 10 according to a preferred embodiment of the invention is shown. FIG. 1 depicts the semiconductor device package 10 with the encapsulant 12 (not shown in FIG. 1) removed from above the upper surface of the leadframe 14. The leadframe 14 typically has a die pad 16 and numerous lead fingers 18. According to this preferred embodiment, the die pad 16 and each of the lead fingers 18 have boreholes 20. It should be understood that the invention may alternatively be implemented with various combinations of boreholes 20 in either the die pad 16, some or all of the lead fingers 18, or both, as further described. The locations of the boreholes 20 may also be varied. For example, offset boreholes 48 may be used. The boreholes 20 may perforate the leadframe 14 or may be non-perforating. The boreholes 20 may be circular as shown at reference numeral 22, or oval 24, rectangular 26, or other shape convenient to the manufacturing process and available area without departure from the invention.

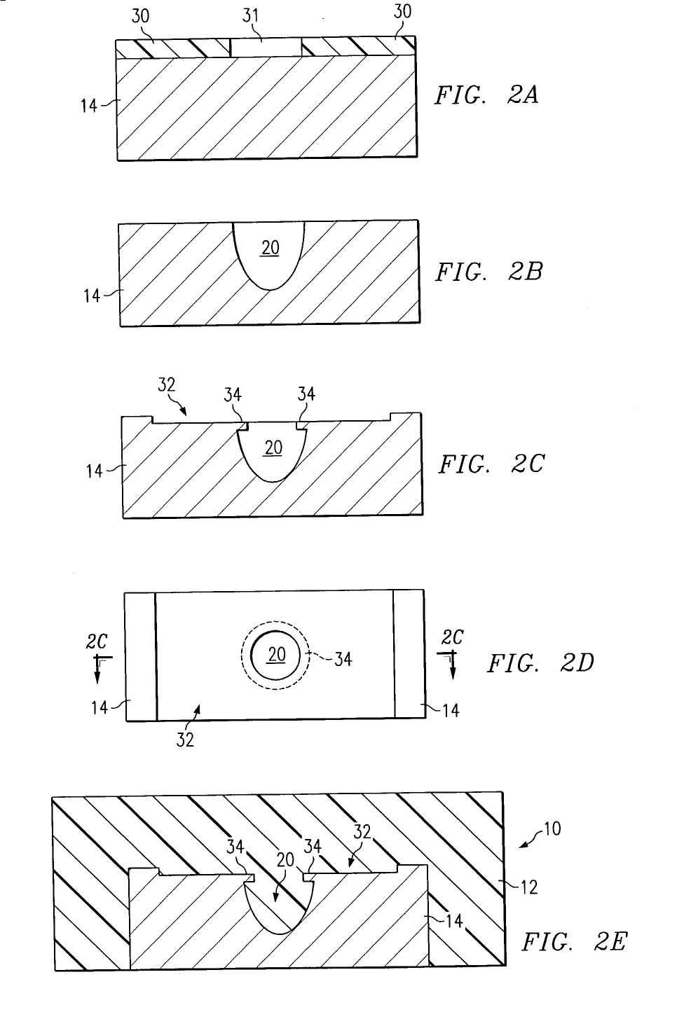

With reference to FIGS. 2A through 2E, examples of preferred embodiments of a semiconductor device package 10 according to the invention and methods of manufacturing are described.

In FIG. 2A, a section of a metallic leadframe 14 is shown preparatory to forming a borehole 20 (not shown in FIG. 2A) in the leadframe 14. The leadframe 14 is preferably masked 30 and a pattern 31 formed for etching using suitable masking and etching techniques known in the arts. In this example, as shown in FIG. 2B, a borehole 20 is etched into the leadframe 14 material. Alternatively, boreholes may be formed in the leadframe by other techniques such as, for example, stamping or laser drilling. Preferably, numerous boreholes 20 are provided in the leadframe 14. The boreholes 20 may be arbitrarily placed, or may be placed in locations selected according to predicted or empirically determined mechanical stress points. The boreholes 20 may also be placed on either or both surfaces of the leadframe 14, and may be of uniform or varying depth, or may perforate through the leadframe 14. The shapes and depths of the boreholes 20 may be varied, as in the examples of FIG. 1. The exact locations and configurations of the boreholes, and techniques used in their formation, are not crucial to the concept of the invention. Referring to FIG. 2B, a section view of a portion of the leadframe 14 is shown. The borehole 20 has been etched as shown and described with reference to FIG. 2A, and the masking material 30 has been removed.

As shown in the example of FIG. 2C, the leadframe 14 is coined in a selected area 32. The coining, or stamping, is performed using tools and methods familiar in the arts, and may be performed as a separate step or as part of a downsetting step. The coined area 32 encompasses the borehole 20 shown in FIG. 2B. The coining forms a metal lip 34 at the junction of the borehole 20 and the leadframe 14 surface. The lip 34 is a result of the application of coining force on the leadframe 14 and is not dependent upon the size or shape of the borehole 20 nor upon the particular technique used in its formation.

A top view of the leadframe 14 portion of FIG. 2C is shown in FIG. 2D. The coined area 32 is shown encompassing the borehole 20. A lip 34 has been formed by the deformation of the metal at the junction of the leadframe 14 surface and borehole 20. It should be appreciated by those skilled in the arts that coining may be performed as a part of the leadframe manufacturing process, or may be performed as a preliminary step in employing a leadframe in manufacturing a semiconductor device package.

An example of the leadframe 14 depicted in FIGS. 2C and 2D as it may appear incorporated into a completed semiconductor package 10 according to a preferred embodiment of the invention is shown in FIG. 2E. The leadframe 14 and borehole 20 are encapsulated with dielectric material 12, typically a form of hard-curing plastic or epoxy resin, generally referred to as plastic or mold compound. The mold compound 12 encapsulates the lip 34 formed at the junction of the borehole 20 and leadframe 14, providing a leadframe-to-plastic lock.

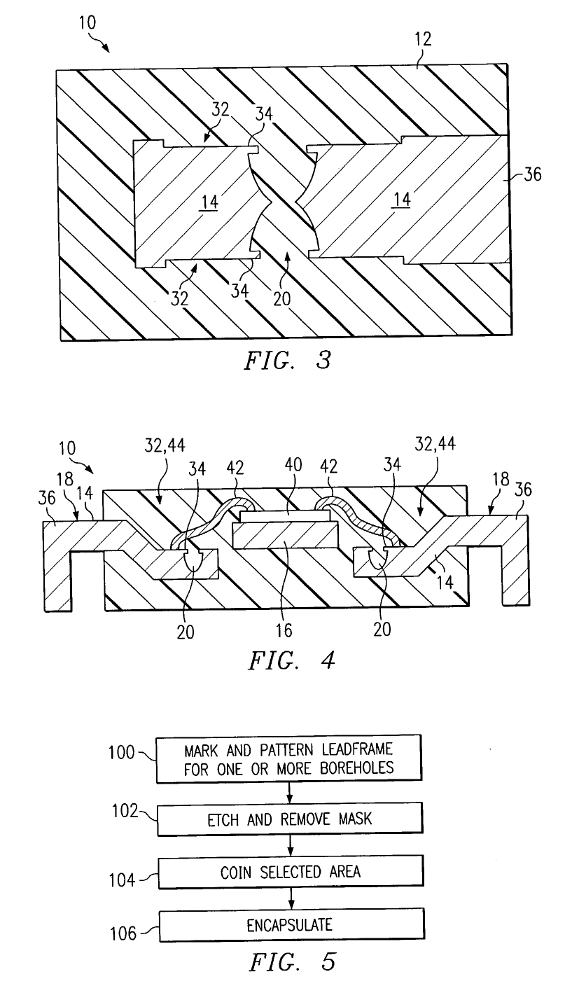

Another example of a preferred embodiment of a semiconductor device package 10 according to the invention is illustrated in FIG. 3. The borehole 20 perforates through the leadframe 14. In this example, each opposing surface of the leadframe 14 has a coined area 32 encompassing the borehole 20. A lip 34 is formed at each junction of the borehole 20 and leadframe 14 surface. Encapsulant 12 engages the lips 34 to form a secure bond, in this case also surrounding the leadframe 14 on all surfaces except for an electrical contact 36 at the outside of the package 10.

FIG. 4 illustrates an example of an embodiment of the invention in a DIP semiconductor device package 10. A semiconductor device 40 is affixed to the bond pad 16 of the leadframe 14. The semiconductor device 40 is electrically coupled to the lead fingers 18 of the leadframe through wires 42 as known in the arts.

In some instances, it is known to apply a “downset ”to selected areas of a leadframe, for example, to offset the lead tip 36 downward in relation to the die pad 16. Typically, the downset is approximately equal to the thickness of the leadframe material. The invention may be practiced in combination with coining and downsetting used in the arts. In this example, a portion 44 of the leadframe 14 has been downset. The downset portion 44 preferably generally corresponds to the coined portion 32 of the leadframe 14 and creates the lip 34.

The boreholes 20 of the coined portion 32 of the leadframe have lips 34 formed at their junctions with the leadframe 14 surface. Mold compound 12 encapsulates the semiconductor device 40 and leadframe 14, except for the contact areas 36, as is typical in the arts. Thus, the advantages of the leadframe-to-plastic lock of the lips 34 are provided in a semiconductor device package 10. Although the invention is shown in the context of a DIP package, the invention may also be used with other packages using a metallic leadframe or die pad, e.g., QFN, SIP, SOIC, SSOP, TSSOP, TVSOP.

FIG. 5 is a process flow diagram illustrating the basic steps in a preferred method of the invention. As shown in step 100, a leadframe is masked and patterned for the formation of at least one borehole. The borehole is etched and the mask material is removed according to semiconductor processing techniques known in the arts, step 102. The borehole may penetrate partially or entirely through the leadframe material. In step 104, a portion of the leadframe that contains at least one borehole is coined. The coining may include the entire leadframe, and may be performed separately or in combination with the downsetting of a portion of the leadframe, so long as the coining causes the formation of a lip at the junction between the borehole and the leadframe surface. The borehole lip is encapsulated, at step 106, with mold compound during the process of assembling the semiconductor device package as known in the arts, forming a secure mechanical lock structure.

Of course many variations are possible and some of the steps shown may be performed simultaneously according to known methods of manufacture. For example, the masking steps, or etching steps, may be combined. Additional steps commonly used in the manufacture of IC packages may also be used in implementing the invention. For example, a stamping or drilling step may be substituted for the masking and etching steps used to form the boreholes. It will be appreciated by those skilled in the arts that the invention may be used with various types of device packages, such as DIP, SIP, SOIC, SSOP, TSSOP, TVSOP, and QFN packages, for example.

Thus, the invention provides semiconductor device packages, and methods used in their construction, providing secure mechanical bonds resistant to separation and sheer. Numerous technical advantages are provided by the invention, including but not limited to improved package strength, resilience, longevity, manufacturability, and reliability. While the invention has been described with reference to certain illustrative embodiments, the description of the methods, systems, and devices described are not intended to be construed in a limiting sense. Various modifications and combinations of the illustrative embodiments as well as other advantages and embodiments of the invention will be apparent to persons skilled in the art upon reference to the description and claims.

We claim:

1. A method for manufacturing a packaged semiconductor device comprising the steps of:
forming a leadframe;
forming at least one borehole in the leadframe;
coining a leadframe portion having at least one borehole such that a lip is formed at the junction of the borehole and a leadframe surface; and
encapsulating the lip with mold compound.

2. The method of claim 1 wherein the step of forming at least one borehole further comprises perforating through the leadframe.

3. The method of claim 2 wherein the step of coining further comprises forming a lip at each junction of the borehole and upper and lower leadframe surfaces.

4. The method of claim 1 further comprising a step of downsetting an area of the leadframe.

5. The method of claim 4 further comprising a step of downsefting a die pad of the leadframe.

6. The method of claim 4 wherein the downsetting step is performed in combination with the coining step.

7. A method for manufacturing a semiconductor device package comprising the steps of:
forming a leadframe having a die pad and a plurality of lead fingers;
forming a plurality of boreholes in the leadframe, at least one of the boreholes having a lip; and
encapsulating the lip forming a mold lock for the semiconductor device package.

8. The method of claim 7 wherein the step of forming at least one borehole further comprises perforating through the leadframe.

9. The method of claim 7 further comprising the step of coining a leadframe portion having at least one borehole thereby forming a lip at a junction of the borehole and a surface of the leadframe.

10. The method of claim 7 further comprising a step of downsetting a portion of the leadframe.

11. The method of claim 7 further comprising a step of downsetting a die pad of the leadframe.

12. The method of claim 10 wherein the downsetting step is performed in combination with the coining step.

13. The method of claim 7 wherein at least one borehole having a lip is formed in a lead finger of the leadframe.

14. The method of claim 7 wherein at least one borehole having a lip is disposed in a die pad of the leadframe.

15. A semiconductor device package comprising:
a leadframe having a borehole, the borehole having a lip; and
mold compound disposed in the borehole and encapsulating the lip.

16. A semiconductor device package according to claim 15 wherein the borehole further comprises a perforation through the leadframe.

17. A semiconductor device package according to claim 16 further comprising a lip at each junction of the borehole and upper and lower leadframe surfaces.

18. A semiconductor device package according to claim 15 wherein at least one borehole is disposed in a lead finger of the leadframe.

19. A semiconductor device package according to claim 15 wherein at least one borehole is disposed in a die pad of the leadframe.

20. A semiconductor device package according to claim 15 wherein the mold compound fills the borehole.
